(19) United States
(12) Patent Application Publication
(10) Pub. No.: US 2018/0086664 A1
(43) Pub. Date: Mar. 29, 2018

(54) GLASS-SENSOR STRUCTURES

(71) Applicant: VAON, LLC, Bowling Green, KY (US)

(72) Inventors: Henry Steen, Bowling Green, KY (US); Alexander Larin, Bowling Green, KY (US); Jon Paschal, Bowling Green, KY (US); Quentin Lineberry, Bowling Green, KY (US); Keith Andrew, Bowling Green, KY (US); Phillip Womble, Bowling Green, KY (US)

(21) Appl. No.: 15/717,581

(22) Filed: Sep. 27, 2017

Related U.S. Application Data
(60) Provisional application No. 62/400,152, filed on Sep. 27, 2016.

(51) Int. Cl. C03C 17/00; B81B 7/00; C03C 17/02; B32B 17/06

(52) U.S. Cl. CPC C03C 17/002; B81B 7/0058; C03C 17/02; B81B 7/0025; B81B 7/0038; B81B 7/0019; B32B 17/06

(57) ABSTRACT

The present invention generally relates to glass-sensor structures and methods of making the same.

### FIELD OF THE INVENTION

The present invention generally relates to glass-sensor structures and a method of manufacturing glass-sensor structures.

### BACKGROUND OF THE INVENTION

Thermal isolation and stability are critical elements contributing to the precise operation of MEMS (microelectromechanical systems) devices in general and high-temperature MEMS devices in particular. Typically, there is intrinsic complexity in fabricating MEMS devices.

The silicon on chip approach to MEMS fabrication requires complicated multi-step and time consuming processes in a clean room environment. Some silicon on chip fabrication processes require the use of extremely hazardous chemicals.

In view of the above, it is advantageous to develop new types of and methods of manufacturing MEMS devices to achieve higher levels of thermal, mechanical, and chemical resistance and stability compared to current state-of-the-art technology with silicon on chip.

### SUMMARY OF THE INVENTION

In another aspect, the present invention provides a novel glass-sensor structure.

In an aspect, the present invention provides a novel method of manufacturing glass-sensor structures.

These and other aspects, which will become apparent during the following detailed description, have been achieved by the inventors' discovery of a new glass-sensor structure.

### BRIEF DESCRIPTION OF THE DRAWINGS

FIG. 1 shows the dimensions of a piece of flat glass.

FIG. 2 shows a piece of flat glass with 4 circular cut outs.

FIG. 3 shows a piece of flat glass with a cut out.

FIG. 4 shows a piece of flat glass with a cut out.

FIG. 5 shows a piece of flat glass with a cut out.

FIG. 6 shows a sensor glass layer wherein the sensory element is on top of Layer A.

FIG. 7 shows sensor glass layer of FIG. 6 wherein some of the glass of Layer A near the edges of the sensory element has been removed.

FIG. 8 shows an expanded view of a glass-sensor structure having Layers A-E, wherein the sensory element is on top of Layer A.

FIG. 8A shows an expanded view of a glass-sensor structure having Layers A-E, wherein the sensory element is on top of Layer A and the layers are connected by conductive pins that extend beyond the glass-sensor structure (for externally connecting the sensor).

FIG. 8B shows an expanded view of a glass-sensor structure having Layers A-E, wherein the sensory element is on top of Layer A, the layers are connected by conductive pins, and the bottom layer has conductive pads (for externally connecting the sensor).

FIG. 9 is a collapsed view of the glass-sensory structure of FIG. 8.

FIG. 9A is a collapsed view of the glass-sensory structure of FIG. 8A.

FIG. 9B is a collapsed view of the glass-sensory structure of FIG. 8B.

FIG. 10 shows an expanded view of a glass-sensor structure having Layers C-A-E.

FIG. 11 is a collapsed view of the glass-sensor structure of FIG. 10.

FIG. 12 shows an expanded view of a glass-sensor structure having layers A-E, wherein the sensory element is in the plane of Layer A.

FIG. 13 shows a collapsed view of the glass-sensor structure of FIG. 12.

FIG. 14 shows a top view of the collapsed view of the glass-sensor structure of FIG. 12.

FIG. 15 shows an expanded view of a glass-sensor structure having Layers C-A-E, wherein the sensory element is in the plane of Layer A.

FIG. 16 shows the top view of the glass-sensor structure of FIG. 15.

FIG. 17 shows a collapsed view of the glass-sensor structure of FIG. 15, with Layer C being shown as translucent.

FIG. 18 is a collapsed view of the glass-sensor structure of FIG. 15.

FIG. 19 shows another example of a glass-sensor structure similar to FIG. 15.

FIG. 20 shows the top view of the glass-sensor structure of FIG. 19.

FIG. 21 shows an expanded view of a glass-sensor structure similar to that of FIG. 19, except that 4 middle portions of Layer A are missing.

FIG. 22 shows a collapsed view of a glass-sensor structure having layers A-E. Layer C is designed to rotate via a gear mechanism.

### DETAILED DESCRIPTION OF THE INVENTION

The present inventors sought a way (or ways) to overcome many of the complexities encountered in the MEMS clean room fabrication process. In an aspect, the present invention results in the combination of high precision and operational stability while minimizing fabrication steps and eliminating all wet chemistry processes from the fabrication procedure. In another aspect, the present invention teaches a methodology to cleanly, safely, and easily produce very high performing MEMS devices with much less complexity and cost compared with current technologies (e.g., silicon-on-a-chip).

Glass: Glass refers to a substance typically formed by melting sand, sodium carbonate (soda), and calcium oxide (lime)(silicate glass). The glass can also be formed with B₂O₃ and/or Al₂O₃ to form borosilicate, aluminosilicate or alumino-borosilicate glass. Additional additives can also be included during the formation of the glass or afterwards (e.g., polymer or metal oxide coatings). The glass can be transparent, translucent, or opaque. For translucent or opaque, the glass can be formed with this property. Alternatively, the glass can be modified to be translucent or opaque. Examples of modification include the addition of a translucent or opaque layer (e.g., a coating on one or both sides of one or more glass layers). The glass can be made or modified such that it reflects (in or out) and/or filters (in or out) certain wavelengths of light. In another aspect, a modified glass layer can further comprise another glass layer (e.g., to sandwich a coating to protect and/or enhance the modification).

Flat: Flat refers to the roughness of the glass. Examples of the roughness average (Ra) of the glass include less than 5, 4, 3, 2, 1, 0.9, 0.8, 0.7, 0.6, 0.5, 0.4, 0.3, 0.2, and 0.1 nm. Examples of peak-to-valley roughness (Rpv) include less than 50, 45, 40, 35, 30, 25, 20, 15, 10, and 5 nm.

Examples of the thickness of the glass used in the present invention include 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, 200, 205, 210, 215, 220, to 225 μm, or greater.

As an example, the presently claimed invention uses glass that is stable to at least 600° C. Other examples of the temperature at which the glass remains stable includes 625, 650, 675, 700, 725, 750, 775, and 800° C.

Examples of commercially available flexible, flat glass include ultra-thin glass from Schott (e.g., AF 32® eco and AF 32® eco) as well as Corning® Willow® glass.

Typically, the glass used in the present invention is flexible. For example, the glass is bendable or capable of forming a curved structure without shattering (e.g., a non-brittle substance).

Middle Portion:

Middle portion refers to an area of a glass piece that is not touching an edge of the glass piece. A glass piece can have one or a plurality of middle portions removed. The removed portions are called cut outs. A glass piece can have 1, 2, 3, 4 or more cut outs. As an example, in one aspect, one of layers of glass in the 3D structure has 4 non-touching square sections cut out (leaving a plus (+) shape in the middle of the glass). Stacking a glass piece on top of and below this layer will provide 4 spaces corresponding to the 4 cutouts. One benefit of creating one or more spaces between layers is it allows for the high temperature sensor to be both electrically and thermally isolated (at least partially) from its surroundings.

Sensory Element:

Sensory element refers to any type of sensor that would benefit from the structures described herein (e.g., a multi-layered glass structure). Examples of sensors include low temperature sensors, high temperature sensors, liquids sensors, enzymatic sensors, and optical/light sensors. Typically the sensor detects the present of an analyte (e.g., gas or light) via a measurable change in electrical conductance. One example of a high-temperature sensor is a metal oxide sensor (e.g., SnO₂). The sensory element, typically, comprises: at least one sensor (e.g., a metal or metal oxide or two or more layers of the same or different metals and/or metal oxides), optionally at least one heater, and at least one pair of electrodes capable of detecting changes to the sensor.

Examples of the thickness of the sensor used in the present invention include 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, 200, 205, 210, 215, 220, to 225 μm, or greater.

Environmentally Connected:

Environmentally connected means that the inside of the glass-sensor structure is connected to the environment that surrounds it (or at least part of it). The environment that surrounds the glass-sensor structure includes gas, liquid, light, etc. and mixtures thereof. For example, a layer in the glass-sensor structure can have a channel from an outside edge to an inner space, such that there is a direct connection from the environment to the inside of the glass-sensor structure. In an aspect, the channel is formed in one layer (e.g., Layer B can have 1 (or alternatively 2 or more) channel in it). In another embodiment, the channel is formed by two layers (e.g., Layer B, comprises: a 1^{st} and 2^{nd} layer).

In an aspect, the present invention provides a novel glass-sensor structure: comprising:

a sensor glass layer, comprising:
Layer A: a flat glass layer, optionally comprising: a reflective surface on its top or bottom; and,
a sensory element;
optionally, the glass-sensor structure, further comprises: from 1-4 layers selected from;
   Layer B: a flat glass layer located on top of and at least partially in contact with Layer A, provided that if Layer B is present, Layer C is also present;
   Layer C: a flat glass layer located on top of and at least partially in contact with Layer B, if present, or Layer A if Layer B is not present, and optionally comprising: a reflective surface on its top or bottom;
   Layer D: a flat glass layer located on the bottom of and at least partially in contact with Layer A, provided that if Layer D is present, Layer E is also present; and
   Layer E: a flat glass layer located on the bottom of and at least partially in contact with Layer D, if present, or Layer A if Layer D is not present, and optionally comprising: a reflective surface on its top or bottom.

In another aspect, the present invention provides a novel glass-sensor structure, wherein the sensor glass layer, comprises: a plurality (more than 1) of sensory elements. Examples of plurality include 2, 3, 4, 5, 6, 7, 8, 10, 11, 12, 13, 14, 15, 16, 17, 18, 19, 20, 21, 22, 23, 24, 25, 26, 27, 28, 29, 30, 32, etc. The number of sensory elements on Layer A is only limited by the starting size of Layer A and the size of each individual sensory element. A sensor glass layer, comprising: a plurality of sensors, can be cut into multiple sensor glass layers. For example, if there are 64 sensory elements on Layer A, then this sensor glass layer can be cut into 16 sensor glass layers, each with 4 sensory elements thereon. In another example, the 64-sensory element layer can be cut into 4 sensor glass layers, each with 16 sensory elements. In another example, the 64-sensory element layer can be cut into 64 sensor glass layers, each with 1 sensory element.

In another aspect, parts of the sensor can also be present on the bottom of Layer A.

Sensory Element on Top

Sensory Element on Top-Layer A:

In another aspect, the present invention provides a novel glass-sensor structure, wherein the sensory element is in contact with at least a portion of the top of Layer A and has a smaller surface area than Layer A. In another aspect, the sensory element is built directly onto the top of Layer A. In another aspect, the sensory element is attached (e.g., glued) to the top of Layer A. In another aspect, a middle portion of Layer A located under the sensory element is absent.

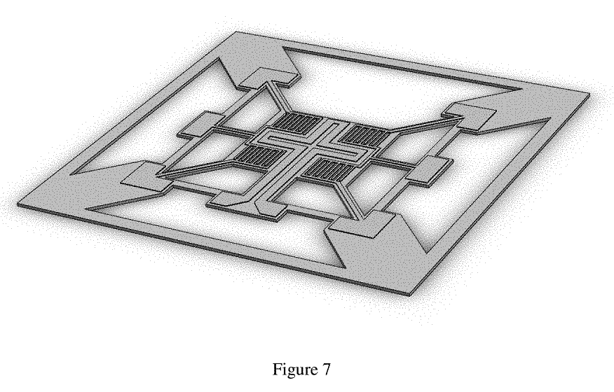

In another aspect, the present invention provides a novel glass-sensor structure, wherein the glass of Layer A near the edges of the sensory element is partially absent. An example of this is shown in FIG. 7. Removal of the glass near the edges of the sensory element helps to isolate the sensor from the glass-sensor structure. Isolating the sensor can provide benefits such as thermal stability and decreased power consumption.

In another aspect, the present invention provides a novel glass-sensor structure, wherein the reflective surface is present on Layer A. The reflective surface, when present, partially or fully covers Layer A (and/or Layer C and/or Layer E). In an example, the reflective surface does not extend to the edges of layer A (and/or Layer C and/or Layer E). The reflective surface can be present on the top or bottom of the layer. In another aspect, the reflective surface is on the bottom of Layer A.

Sensory Element on Top-Layers A, B, and C:

In another aspect, the present invention provides a novel glass-sensor structure, wherein Layers B and C are present. In another aspect, a middle portion of Layer B is absent, such that an inner portion of Layer B is near the edges of the sensory element. Typically, when the sensory element is on top of Layer A, Layer B is not in contact with the sensory element. In another aspect, there is a least one channel in Layer B (and/or Layer E when present) from an outside edge through to an absent middle portion. This channel forms an environmental connection and allows for a gasses to flow into or out of the space between layers A and C (and/or A and E), which is formed by the absence of a middle portion of Layer B (and/or Layer D). Alternatively, Layer B (and/or Layer D) comprises: 1^{st} and 2^{nd} glass layers that when placed in contact form the channel, but separately do not have a complete channel in them (e.g., the 1^{st} layer has a partial channel from an outside edge and the 2^{nd} layer has a partial channel from an inside edge (from the space formed by the absence of a middle portion) such that when the two layers are contacted the two partial channels overlap and form the complete channel).

In another aspect, the present invention provides a novel glass-sensor structure, wherein a middle portion of Layer C is absent. A middle portion of Layer C being absent connects the sensor to the environment when the absent portions of Layers and B and C at least partially overlap. In another aspect, the reflective surface is present on Layer C. In another aspect, the reflective surface is on top of Layer C. In another aspect, the reflective surface is on bottom of Layer C.

Sensory Element on Top-Layers A, B, C, D, and E:

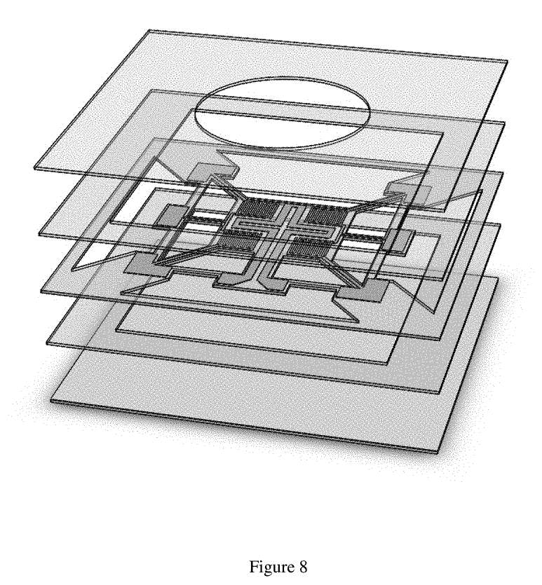

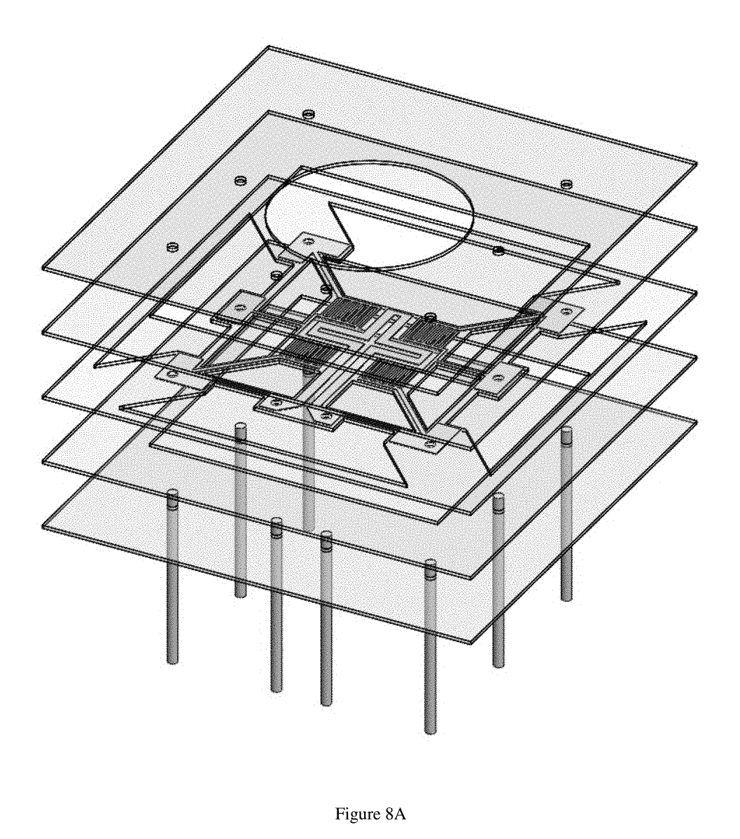

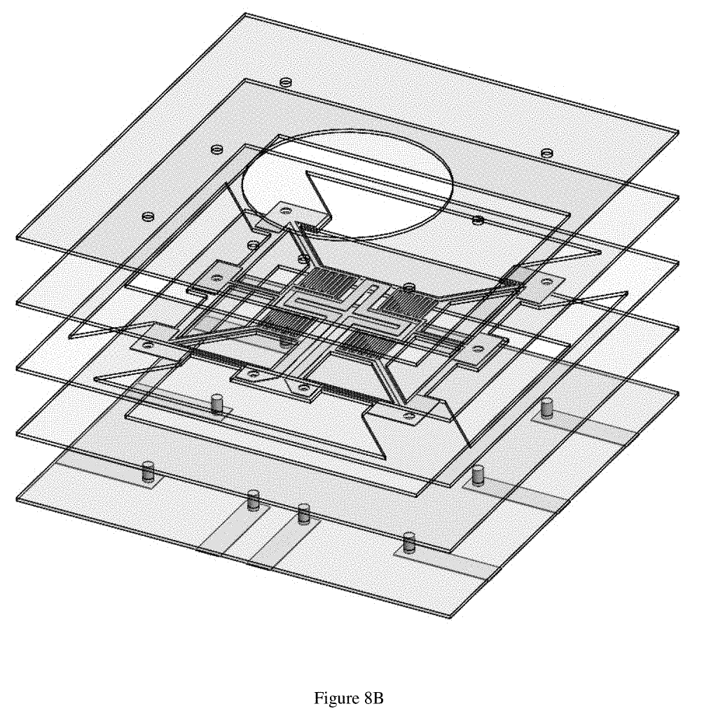

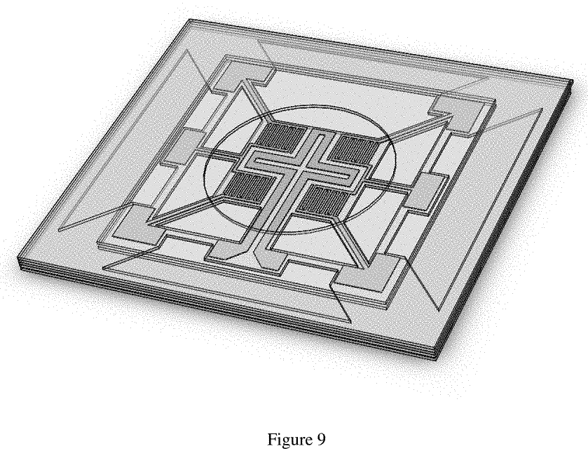

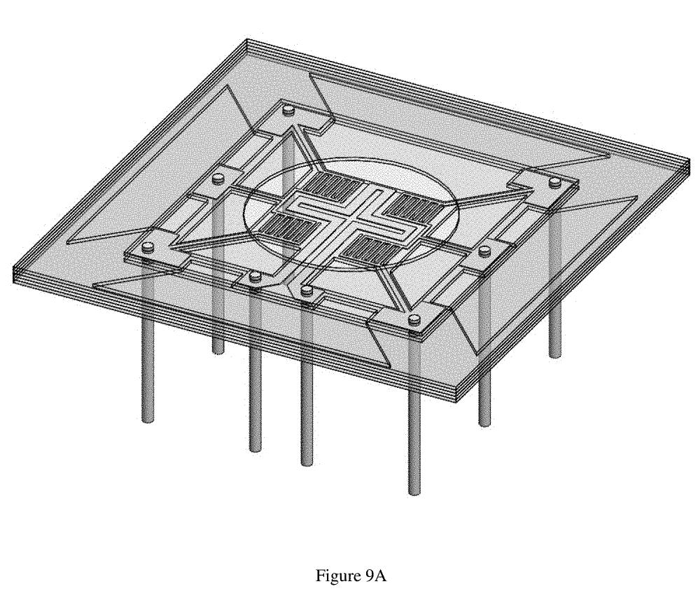

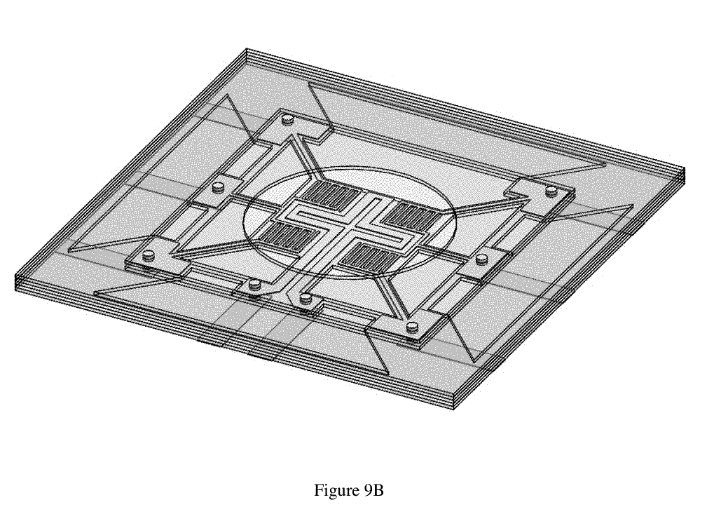

In another aspect, the present invention provides a novel glass-sensor structure, wherein Layers B, C, D, and E are present. An example of this type of glass-sensor structure can be seen in FIGS. 8-9. Layers B and C are as described above. In another aspect, a middle portion of Layer D is absent. In another aspect, a middle portion of Layer E is absent. This connects the bottom of Layer A to the environment when the absent portions of Layers and D and E at least partially overlap. In another aspect, this connects the sensor to the environment if a middle portion of Layer A is also absent and overlaps with the D/E overlap. In another aspect, the reflective surface is present on Layer E. In another aspect, the reflective surface is on the bottom of Layer E. In another aspect, the reflective surface is on the top of Layer E.

Sensory Element on Top-Layers A, B, C, and D:

In another aspect, the present invention provides a novel glass-sensor structure, wherein Layers B, C, and E are present and Layer D is absent. In another aspect, a middle portion of Layer E is absent. This connects the bottom of Layer A to the environment. In another aspect, this connects the sensor to the environment if a middle portion of Layer A is also absent and overlaps with the absent portion of Layer E. In another aspect, the reflective surface is present on Layer E. In another aspect, the reflective surface is on the bottom of Layer E. In another aspect, the reflective surface is on the top of Layer E.

Sensory Element on Top-Layers A and C:

In another aspect, the present invention provides a novel glass-sensor structure, wherein Layer B is absent and Layer C is present. In another aspect, a middle portion of Layer C is absent. This connects the sensor to the environment. In another aspect, the reflective surface is present on Layer C. In another aspect, the reflective surface is on the bottom of Layer C. In another aspect, the reflective surface is on the top of Layer C.

Sensory Element on Top-Layers C, D, and E:

In another aspect, the present invention provides a novel glass-sensor structure, wherein Layers C, D, and E are present and Layer B is absent. Layer C is as described above. In another aspect, a middle portion of Layer D is absent. In another aspect, a middle portion of Layer E is absent. In another aspect, the reflective surface is present on Layer E. In another aspect, the reflective surface is on the bottom of Layer E. In another aspect, the reflective surface is on the top of Layer E.

Sensory Element on Top-Layers A, C, and E:

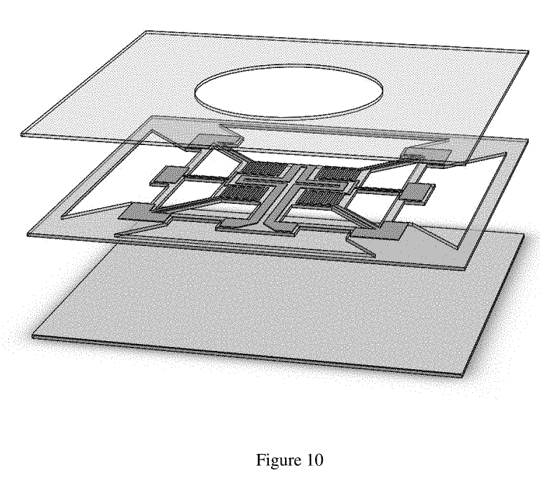

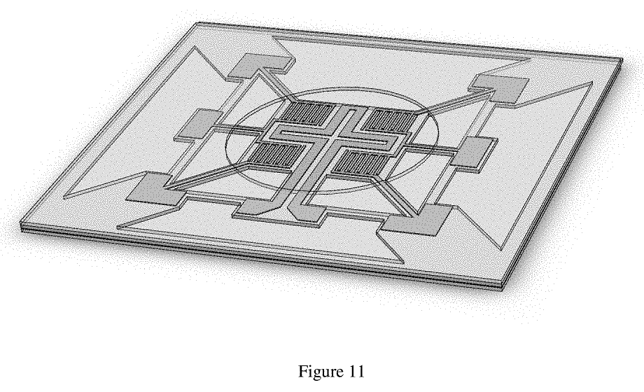

In another aspect, the present invention provides a novel glass-sensor structure, wherein Layers C and E are present and Layers B and D are absent. An example of this type of glass-sensor structure can be seen in FIGS. 10-11. Layer C is as described above. In another aspect, a middle portion of Layer E is absent. In another aspect, the reflective surface is present on Layer E. In another aspect, the reflective surface is on the bottom of Layer E. In another aspect, the reflective surface is on the top of Layer E.

Sensory Element on Top-Layers A, D, and E:

In another aspect, the present invention provides a novel glass-sensor structure, wherein Layers D and E are present. In another aspect, a middle portion of Layer D is absent. In another aspect, a middle portion of Layer E is absent. In another aspect, the reflective surface is present on Layer E. In another aspect, the reflective surface is on the bottom of Layer E. In another aspect, the reflective surface is on the top of Layer E.

Sensory Element on Top-Layers A and E:

In another aspect, the present invention provides a novel glass-sensor structure, wherein Layer D is absent and Layer E is present. In another aspect, a middle portion of Layer E is absent. In another aspect, the reflective surface is present on Layer E. In another aspect, the reflective surface is on the bottom of Layer E. In another aspect, the reflective surface is on the top of Layer E.

Sensory Element in Plane

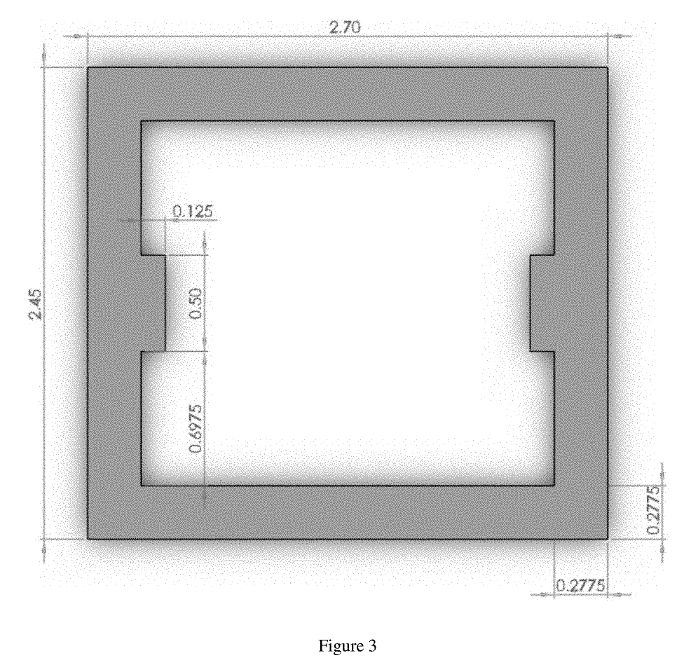

In another aspect, the present invention provides a novel glass-sensor structure, wherein the sensory element is in the same plane as Layer A and is housed in an opening in the middle of Layer A that is at least the size of the sensory element. In this aspect, Layer A “houses” the sensory element by having an opening in it that is large enough to fit the sensory element. This opening can be just large enough to fit the sensor (e.g., at least the size of the sensory element) or large enough that the sensor does not contact Layer A. Typically, Layer A will have one or more (e.g., a plurality) contact points with the sensory element. These contact points are edge-to-edge contact points (i.e., an edge portion of Layer A with an edge portion of the sensory element). For example, an edge of a protrusion or tab in the middle of Layer A can be in contact with an edge of the sensory element (e.g., see FIGS. 3-5, 15, 19, and 21). Examples of the number of these contact points include 1, 2, 3, 4, 5, 6, 7, 8, 9, 10, or more. The contact can also be continuous. For example, one complete edge (e.g., one side of a square or rectangular shaped sensory element) of the sensory element can be in contact with an edge of Layer A. In another example, all four edges of a square, rectangular, or similarly shaped sensor, can be in contact with Layer A.

Sensory Element in Plane—Layers A, B, C, D, and E:

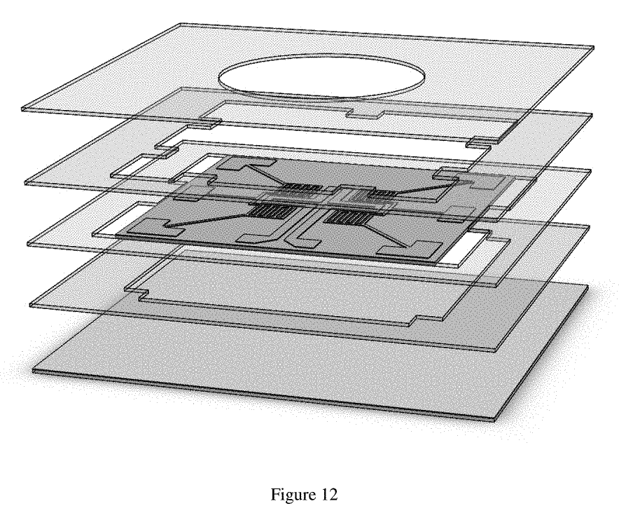

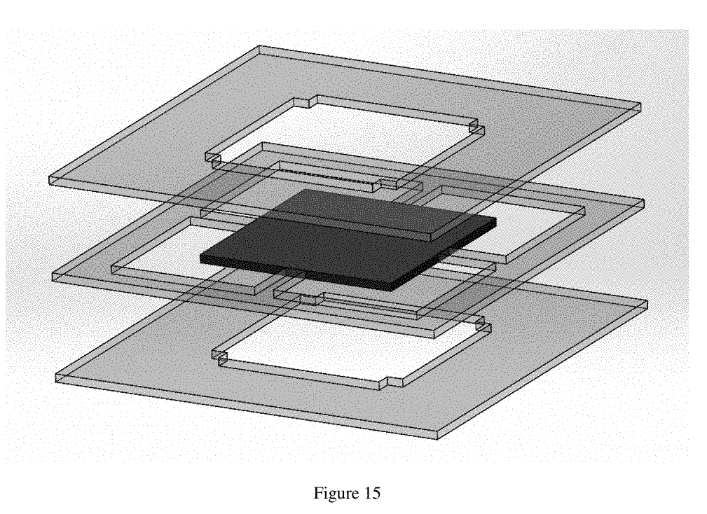

In another aspect, the present invention provides a novel glass-sensor structure, wherein Layers B, C, D, and E are present. An example of this type of glass-sensor structure can be seen in FIGS. 12-14. In another aspect, a middle portion of Layer B is absent and Layer B partially overlaps and is in contact with the sensory element in at least one location. Layer B (also C, D, and/or E) can have planar contact with the sensory element. For example, the top of the sensory element can be in contact with the bottom of Layer B (or C). Also, the bottom of the sensory element can be in contact with the top of Layer D (or E). This contact can be in one or more (e.g., a plurality) of locations. For example, the bottom of a protrusion or tab in the middle of Layer B (or C) can be in contact with top of the sensory element (e.g., see FIGS. 15, 19, and 21). In another example, the top of protrusion or tab in the middle of Layer D (or E) can be in contact with the bottom of the sensory element (e.g., see FIGS. 15, 19, and 21). Examples of the number of these type of contact points include 1, 2, 3, 4, 5, 6, 7, 8, 9, 10, or more. The contact can also be continuous. For example, one complete edge (e.g., a square or rectangular shaped sensory element) of the sensory element overlaps and can be in contact with the bottom of Layer B (or C or the top of D or E). In another example, four edges of a square, rectangular, or similarly shaped sensor, overlap and are in contact with bottom of Layer B (or C or the top of D or E).

In another aspect, the present invention provides a novel glass-sensor structure, wherein a middle portion of Layer C is absent. This connects the sensor to the environment when the absent portion of Layer C at least partially overlaps the opening in Layer B and the sensory element. In another aspect, the reflective surface is present on Layer C. In another aspect, the reflective surface is on the bottom of Layer C. In another aspect, the reflective surface is on the top of Layer C.

In another aspect, the present invention provides a novel glass-sensor structure, wherein a middle portion of Layer D is absent and Layer D partially overlaps and is in contact with the sensory element in at least one location. In another aspect, a middle portion of Layer E is absent. This connects the sensor to the environment when the absent portion of layer E at least partially overlaps the opening in Layer D and the sensory element. In another aspect, the reflective surface is present on Layer E. In another aspect, the reflective surface is on the bottom of Layer E. In another aspect, the reflective surface is on the top of Layer E.

Sensory Element in Plane—Layers A, B, C, and E:

In another aspect, the present invention provides a novel glass-sensor structure, wherein Layers B, C, and E are present and D is absent. In another aspect, a middle portion of Layer B is absent and Layer B partially overlaps and is in contact with the sensory element in at least one location. In another aspect, a middle portion of Layer C is absent. In another aspect, the reflective surface is present on Layer C. In another aspect, the reflective surface is on the bottom of Layer C. In another aspect, the reflective surface is on the top of Layer C. In another aspect, a middle portion of Layer E is absent. In another aspect, the reflective surface is present on Layer E. In another aspect, the reflective surface is on the bottom of Layer E. In another aspect, the reflective surface is on the top of Layer E.

Sensory Element in Plane—Layers A, C, D, and E:

In another aspect, the present invention provides a novel glass-sensor structure, wherein Layers C, D, and E are present and Layer B is absent. In another aspect, a middle portion of Layer C is absent and Layer C partially overlaps and is in contact with the sensory element in at least one location. In another aspect, the reflective surface is present on Layer C. In another aspect, the reflective surface is on the bottom of Layer C. In another aspect, the reflective surface is on the top of Layer C. In another aspect, a middle portion of Layer D is absent and Layer D partially overlaps and is in contact with the sensory element in at least one location. In another aspect, a middle portion of Layer E is absent. In another aspect, the reflective surface is present on Layer E. In another aspect, the reflective surface is on the bottom of Layer E. In another aspect, the reflective surface is on the top of Layer E.

Sensory Element in Plane—Layers A, C, and E:

In another aspect, the present invention provides a novel glass-sensor structure, wherein Layers C and E are present and Layers B and D are absent. Examples of this type of glass-sensor structure can be seen in FIGS. 15-21. In another aspect, a middle portion of Layer C is absent and Layer C partially overlaps and is in contact with the sensory element in at least one location. In another aspect, the reflective surface is present on Layer C. In another aspect, the reflective surface is on the bottom of Layer C. In another aspect, the reflective surface is on the top of Layer C. In another aspect, a middle portion of Layer E is absent and Layer E partially overlaps and is in contact with the sensory element in at least one location. In another aspect, the reflective surface is present on Layer E. In another aspect, the reflective surface is on the bottom of Layer E. In another aspect, the reflective surface is on the top of Layer E.

Movable Layers: Sensory Element on Top or in Plane

One of the problems encountered when sensors are placed in the real world is damage caused to the sensor by the environment. The damage can be caused by weather (e.g., rain or humidity), dust, light, etc. A way to prevent, slow, or limit sensory element damage is to limit its exposure to the environment. Exposure of the sensor to its surrounding environment can be limited by one of Layers B, C, D, and/or E acting as a “cover” for (or “covering”) the sensory element. Covering can be achieved by one of Layers A, B, C, D, and/or E being movable. Thus, in another aspect, at least one of Layers A, B, C, D, and E is movable. In another aspect, one of Layers A, B, C, D, and E is movable.

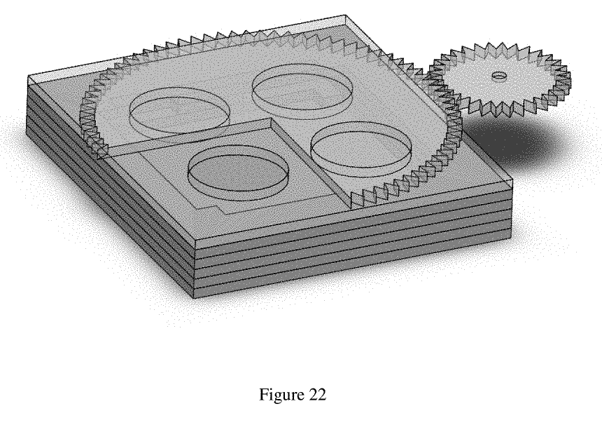

An example of a “sensor covered” type of glass-sensor structure can be seen in FIG. 22. In this example, Layers A-E are present and Layer C (the top layer) is movable. The circumference of Layer C is toothed. The gear shown in FIG. 22 is capable of rotating Layer C over Layer B, which has four openings. In FIG. 22, Layer C has been rotated such that only one opening of Layer B is exposed to the environment. This configuration allows for one part of the sensory element to be exposed. By rotating Layer C stepwise, only one opening of Layer B at a time will be exposed to the environment. Other examples of this configuration would include those where Layer C (or another layer such as Layer E under Layer D or Layer B under Layer C, etc.) can be rotated such that no part of the sensory element is exposed (a closed position). Additional examples would allow for more than one part of the sensory element (or more than one opening in Layer B or another layer) to be exposed simultaneously.

Other examples of movement, besides rotation, include side-to-side motion (e.g., a layer slides in one direction to expose the sensory element to the environment and back to close) and up and down motion (e.g., a layer (or an edge thereof) lifts are raises far enough to allow environmental exposure and then settles back down to close). There are numerous ways to drive movement of a movement layer besides the gear-driven configuration shown in FIG. 22. For example, the movement can be driven by a lever, piezoelectrics, magnetics, etc. In addition, the glass-sensor structure itself can be moved (e.g., tilting or shaking or inverting) to expose the sensor.

Mechanical and Electrical Connectors:

In another aspect, the present invention provides a novel glass-sensor structure as described above, further comprising: a plurality of mechanical pins. These mechanical pins pass through the middle layers of the glass-sensor and at least into the top and bottom layers. Optionally, one or more of the mechanical pins pass through at least one of the top or bottom layer and extend beyond the glass-sensor structure (e.g., see FIGS. 8A and 9A). A benefit of at least one or more pin extending beyond the structure (e.g., extending beyond the bottom layer) is that it allows for external electrical connection with the sensor.

In another aspect, the mechanical pins are electrically conductive and are in electrical connection with the sensor.

In another aspect, the plurality of mechanical pins extend beyond the bottom of the glass-sensor structure, are electrically conductive, and are in electrical connection with the sensor.

In another aspect, the present invention provides a novel glass-sensor structure as described above, further comprising: a plurality of mechanical pins and a plurality of surface mount pads, wherein the pads are located on top of the bottom layer (e.g., layer E) and are in electrical connection with the mechanical pins. Typically, when surface mount pads are present, the mechanical pins are electrically conductive and pass into the outermost layers of the structure, but do not substantially extend beyond these outermost layers.

Methods

In another aspect, the present invention provides a novel method of manufacturing a glass-sensor structure described above, comprising:
(a) applying at least one sensory element to a layer of flat glass to form a sensor glass layer.

In another aspect, the method, further comprises:
(b) stacking at least one layer (e.g., Layer B, C, D, and/or E) of flat glass with the sensor glass layer to form a glass-sensor structure as described above.

In another aspect, the method, further comprises:
(c) fusing the stacked glass layers.
   Examples of methods that can be used to fuse the glass layers include ultrasound and pressure.
   Examples of the number of layers that are fused include 3, 4, 5, 6, 7, 8, 9, and 10.

In another aspect, the method, further comprises:
(d) applying a reflective surface to at least one of Layers A, C, and E.
   As described previously, the reflective surface can be applied to the top or bottom of Layers A, C, and/or E and can partially or fully cover the layer's surface.

In another aspect, the present invention provides a novel method of manufacturing a glass-sensor structure, comprising:
(a) stacking at least one sensor glass layer described above with at least one layer of flat glass (e.g., Layers B, C, D, and/or E described above) to form a glass-sensor structure as described above;

In another aspect, the method, further comprises:
(b) fusing the stacked glass layers.
   Examples of methods that can be used to fuse the glass layers include ultrasound and pressure.
   Examples of the number of layers that are fused include 3, 4, 5, 6, 7, 8, 9, and 10.

In another aspect, the method, further comprises:
(c) applying a reflective surface to at least one of Layers A, C, and E.
   As described previously, the reflective surface can be applied to the top or bottom of Layers A, C, and/or E and can partially or fully cover the layer's surface.

In another aspect, the method of manufacturing, further comprises: cutting the glass layers (with or without a sensory element being present). The cutting can be performed using a laser. The cutting can occur before or after stacking. For example, Layer A, comprising: a plurality of sensory elements can be cut. Also, Layers B-D can be cut from a larger piece of flat glass. Alternatively, Layer A, comprising: a plurality of sensory elements can be stacked with one or more of layers B-D and then cut (with fusing optionally occurring before or after cutting). Alternatively, Layer A, comprising: a plurality of sensory elements can be cut and then stacked with one or more of layers B-D, and optionally fused. It should be noted that a cutting process is used to remove one or more middle portions from one or more of Layers B-D. This cutting usually occurs prior to stacking. This cutting can also occur on a large piece of flat glass that is then stacked or cut and the resulting individual pieces stacked.

In another aspect, the sensor is a chemical sensor, comprising:
(a) an oxidized silicon wafer, comprising: a silicon layer sandwiched between a top (1^{st}) silicon oxide (SiO₂) layer and a bottom (2^{nd}) SiO₂ layer, the top SiO₂ layer, comprising: a sensor area;
(b) a heating element in contact with the 1^{st} SiO₂ layer and located near at least one edge of the sensor area;
(c) a pair of electrical leads in contact with the 1^{st} SiO₂ layer and at least partly located on the sensor area;
(d) a metal oxide layer located on the sensor area and in contact with at least a part of the pair of electrical leads and the 1^{st} SiO₂ layer; and,
(e) a dopant layer in contact with the metal oxide layer.

In another aspect, the sensor is a chemical sensor, comprising:
(a) an oxidized silicon membrane, comprising a silicon (Si) layer and a silicon oxide (SiO₂) layer, wherein the SiO₂ layer is located on top of the silicon layer and, comprises: a sensor area;
(b) a heating element in contact with the SiO₂ layer and located near at least one edge of the sensor area;
(c) a pair of electrical leads in contact with the SiO₂ layer and at least partly located on the sensor area; and,
(d) a metal oxide layer located on the sensor area and in contact with at least a part of the pair of electrical leads and the SiO₂ layer; and,
(e) a dopant layer in contact with the metal oxide layer.

Membrane (sometimes referred to as a “floating” sensor) refers to a SiO₂/Si wafer that is typically formed from an oxidized silicon wafer (e.g., a wafer having SiO₂/Si/SiO₂ layers). The membrane is formed by removing one of the SiO₂ layers (e.g., the bottom layer) and a substantial portion of the Si layer. Typically part of the original wafer (SiO₂/Si/SiO₂) is left to serve as connectors for the membrane (e.g., leaving the 4 corner pieces of the original wafer as the “connectors” to the membrane).

In another aspect, the sensor is a chemical sensor platform, comprising:
(a) an oxidized silicon wafer, comprising: a silicon layer sandwiched between a top (1^{st}) silicon oxide (SiO₂) layer and a bottom (2^{nd}) SiO₂ layer, the 1^{st} SiO₂ layer, comprising: a plurality of separate sensor areas;
(b) at least one heating element in contact with the 1^{st} SiO₂ layer and located near at least one edge of a sensor area;
(c) a plurality of electrical leads, each in contact with the 1^{st} SiO₂ layer, wherein 1 pair of electrical leads is at least partly located on each of the separate sensor areas;
(d) a plurality of metal oxide layers, wherein 1 metal oxide layer is located on each of the plurality of sensor areas and in contact with at least a part of the pair of electrical leads located on the same area; and,
(e) a plurality of dopant layers, wherein 1 dopant layer is located on each of the plurality of sensor areas and in contact with the metal oxide layer in the same area.

In another aspect, the sensor is a chemical sensor platform, comprising:
(a) an oxidized silicon membrane, comprising a silicon (Si) layer and a silicon oxide (SiO₂) layer, wherein the SiO₂ layer is located on top of the silicon layer and, comprises: a plurality of separate sensor areas;
(b) at least one heating element in contact with the SiO₂ layer and located near at least one edge of each sensor area;
(c) a plurality of pairs of electrical leads, each in contact with the SiO₂ layer, wherein 1 pair of electrical leads is at least partly located on each of the separate sensor areas;
(d) a plurality of metal oxide layers, wherein 1 metal oxide layer is located on each of the plurality of sensor areas and is in contact with at least a part of the pair of electrical leads located on the same area; and,
(e) a plurality of dopant layers, wherein 1 dopant layer is located on each of the plurality of sensor areas and in contact with the metal oxide layer in the same area.

The number of sensor areas in the chemical sensor platform varies. Examples include 2, 3, 4, 5, 6, 7, 8, 9, 10, or more. The number of sensor areas determines the number of pairs of electrical leads, metal oxide layers, and dopant layers. The number of heating elements is independent of the number of sensor areas. One heating element can service more than one sensor area. Examples of the number of heating elements includes 1, 2, 3, 4, 5, or more.

In another aspect, the plurality is 4. In another aspect, the number of sensor areas is 4.

In another aspect, in the chemical sensor platform there are 4 separate sensor areas, 1 heating element, 4 pairs of electrical leads, 4 metal oxide layers, and 4 dopant layers.

In another aspect, in the chemical sensor platform there are 4 separate sensor areas, 1 Pt heating element, 4 pairs of Pt electrical leads, 4 SnO₂ (metal oxide) layers, and 4 dopant layers.

In another aspect, in the chemical sensor platform there are 4 separate sensor areas, 1 Pt heating element, 4 pairs of Pt electrical leads, 4 SnO₂ (metal oxide) layers, 4 dopant layers, and 4 Si/SiO₂ connectors.

In another aspect, in the chemical sensor platform there are 4 separate sensor areas, 1 Pt heating element, 4 pairs of Pt electrical leads, 4 SnO₂ (metal oxide) layers, 4 dopant layers, and 4 SiO₂/Si/SiO₂ connectors.

In another aspect, in the chemical sensor platform there are 4 separate sensor areas, 1 Pt/Ti (Ti being the 2^{nd} material) heating element, 4 pairs of Pt/Ti (Ti being the 2^{nd} material) electrical leads, 4 SnO₂ (metal oxide) layers, and 4 dopant layers.

In another aspect, in the chemical sensor platform there are 4 separate sensor areas, 1 Pt/Ti (Ti being the 2^{nd} material) heating element, 4 pairs of Pt/Ti (Ti being the 2^{nd} material) electrical leads, 4 SnO₂ (metal oxide) layers, 4 dopant layers, and 4 Si/SiO₂ connectors.

In another aspect, in the chemical sensor platform there are 4 separate sensor areas, 1 Pt/Ti (Ti being the 2^{nd} material) heating element, 4 pairs of Pt/Ti (Ti being the 2^{nd} material) electrical leads, 4 SnO₂ (metal oxide) layers, 4 dopant layers, and 4 SiO₂/Si/SiO₂ connectors.

The description herein applies to both sensors and platforms, where ever appropriate.

In the chemical sensor (or platform), the 1^{st} SiO₂ layer is typically polished. The sensor area is where at least part of a pair of electrical leads is located as well as the metal oxide and dopant layers. The heating element is not in contact with the electrical leads, the metal oxide layer, or the dopant layer but is located close enough to be able to heat the metal oxide and dopant layers. The dopant layer substantially if not entirely covers the exposed or top side of the metal oxide layer.

In another aspect, the oxidized silicon wafer is about 100, 150, 200, 250, 300, 350, 400, 450, to 500 μm thick. In another aspect, the oxidized silicon wafer is about 200 μm thick.

In another aspect, the part of the 2^{nd} SiO₂ layer located beneath the plurality of sensor areas (or sensor area, if only 1 is present) is absent and a substantial portion of the corresponding silicon layer is absent. In this aspect, part of the bottom of the wafer is absent, including all of the 2^{nd} SiO₂ layer and some of the bottom of the silicon layer.

In another aspect, the corresponding part of the silicon layer located beneath the plurality of sensor areas (or sensor area, if only 1 is present) is about 5, 10, 15, 20, 25, 30, 35, 40, 45, 50, 55, 60, 65, 70, 75, 80, 85, 90, 95, to 100 μm thick. This is measured from the bottom of the 1^{st} SiO₂ layer to the bottom of the wafer (no 2^{nd} SiO₂ layer is present on this part of the silicon layer). In another aspect, the corresponding part of the silicon layer located beneath plurality of sensor areas (or sensor area, if only 1 is present) is about 50 μm thick.

In another aspect, part of the 1^{st} SiO₂ layer at the edges of the plurality of sensor areas (or sensor area, if only 1 is present) is absent, thereby forming a discontinuous trench around the plurality of sensor areas (or sensor area, if only 1 is present). The 1^{st} SiO₂ layer that is in contact with the electrical leads remains. The absence of the 1^{st} SiO₂ layer at the edges of the sensor area, but not including the 1^{st} SiO₂ layer that is in contact with the electrical leads, creates a trench that partially isolates the 1^{st} SiO₂ layer in the sensor area from the 1^{st} SiO₂ layer outside of the sensor area. This trench can be deepened by removal of the silicon at the bottom of the trench. Finally, when the 2^{nd} SiO₂ under the sensor area is removed and part of the corresponding part of the silicon layer is removed, the trench becomes an actual opening. The remaining 1^{st} SiO₂ layer in the sensor area and the corresponding silicon layer underneath are then “floating”. The floating area is called a membrane.

In another aspect, part of the 1^{st} SiO₂ layer at the edges of the plurality of sensor areas (or sensor area, if only 1 is present) and part of the corresponding silicon layer is absent, thereby forming a discontinuous trench around the plurality of sensor areas (or sensor area, if only 1 is present).

In another aspect, in the chemical platform (or chemical sensor):
i. the part of the 2^{nd} SiO₂ layer located beneath the plurality of sensor areas (or sensor area, if only 1 is present) is absent and a substantial portion of the corresponding part of silicon layer is absent; and,
ii. the part of the 1^{st} SiO₂ layer at the edges of the plurality of sensor areas (or sensor area, if only 1 is present) and the silicon layer directly beneath is absent, thereby forming a discontinuous opening around the plurality of sensor areas (or sensor area, if only 1 is present).

In another aspect, the corresponding part of the silicon layer is about 5, 10, 15, 20, 25, 30, 35, 40, 45, 50, 55, 60, 65, 70, 75, 80, 85, 90, 95, to 100 μm thick. This is measured from the bottom of the 1^{st} SiO₂ layer to the bottom of the wafer (no 2^{nd} SiO₂ layer is present on this part of the silicon layer). In another example, the corresponding part of the silicon layer is about 50 μm thick.

In another aspect, the metal oxide of the plurality of metal oxide layers is the same. In another aspect, the metal oxide of the plurality of metal oxide layers is different. In another aspect, the metal oxide layers are the same thickness. In another aspect, all of the metal oxide layers are of different thicknesses.

In another aspect, the dopant of the plurality of dopant layers is the same. In another aspect, the dopant of the plurality of dopant layers is different. In another aspect, all dopant layers are the same thickness. In another aspect, all of the dopant layers are of different thicknesses.

In another aspect, the 1^{st} and 2^{nd} SiO₂ layers (in the sensor or platform) are independently about 200 to 400 nm thick. In another aspect, the 1^{st} and 2^{nd} SiO₂ layers are independently about 300 nm thick.

In another aspect, the at least one heating element (or heating element for the chemical sensor), independently comprises: a 1^{st} material selected from Pt, Au, and poly-silicon. In another aspect, the at least one heating element, comprises: Pt.

In another aspect, the heating element is about 50, 100, 150, 200, 250, 300, 350, 400, 450, 500, 550, 600, 650, 700, 750, 800, 850, 900, 950 to 1,000 nm thick. In another aspect, the heating element is about 300 nm thick.

In another aspect, the heating element, further comprises: a 2^{nd} material layer sandwiched between the 1^{st} SiO₂ layer and the 1^{st} material layer. In another aspect, the 2^{nd} material layer, comprises: a metal selected from Ti and Cr. In another aspect, the 2^{nd} material layer, comprises: Ti. In another aspect, the 2^{nd} material layer is about 1, 2, 3, 4, 5, 6, 7, 8, 9, to 10 nm thick. In another aspect, the 2^{nd} material layer is about 2 nm thick. In another aspect, the 2^{nd} material layer is about 5 nm thick.

In another aspect, the plurality of electrical leads (or electrical lead in the chemical sensor), comprise: a 1^{st} metal layer independently selected from Pt and Au. In another aspect, the plurality of electrical leads, comprise: Pt. In another aspect, the plurality of electrical leads are about 50, 100, 150, 200, 250, 300, 350, 400, 450, 500, 550, 600, 650, 700, 750, 800, 850, 900, 950 to 1,000 nm thick. In another aspect, the plurality of electrical leads (or lead in the chemical sensor) are about 300 nm thick.

In another aspect, the plurality of electrical leads (or electrical lead in the chemical sensor), each further comprise: a 2^{nd} metal, layer sandwiched between the 1^{st} SiO₂ layer and the 1^{st} metal layer. In another aspect, each 2^{nd} metal layer, comprises: a metal independently selected from Ti and Cr. In another aspect, each 2^{nd} metal layer, comprises: Ti. In another aspect, each 2^{nd} metal layer is independently about 1, 2, 3, 4, 5, 6, 7, 8, 9, to 10 nm thick. In another aspect, each 2^{nd} metal layer is independently about 2 nm thick. In another aspect, each 2^{nd} metal layer is independently about 5 nm thick.

In another aspect, the metal oxide layer or plurality of metal oxide layers is deposited via sputtering.

In another aspect, the dopant layer or the plurality of dopant layers is deposited via sputtering.

In another aspect, each metal oxide is independently selected from: SnO₂, ZnO, V₂O₅, WO₃, TiO₂, Al₂O₃, and Fe₂O₃. In another aspect, each metal oxide is SnO₂.

In another aspect, each metal oxide layer is independently about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, to 40 nm thick.

The dopant layer being in contact with the metal oxide layer “dopes” the metal oxide layer. Dopes or dopant refers to the surface modification of the metal oxide layer (e.g., SnO₂) by the dopant layer.

In another aspect, each dopant is independently selected from: Ti, TiO₂, Au, Cu, CuO, Cu₂O, Mo, MoO₂, MoO₃, Ni, NiO, Ni₂O₃, Pt, Pd, Ag, AgO, Ru, RuO₂, Rh, Rh₂O₃, Os, OsO₂, OsO₄, Ir, and IrO₂. In another aspect, the dopant is TiO₂.

In another aspect, each dopant layer is independently about 2, 2.5, 3, 3.5, 4, 4.5, 5, 5.5, 6, 6.5, 7, 7.5, 8, 8.5, 9, 9.5, 10, 10.5, 11, 11.5, 12, 12.5, 13, 13.5, 14, 14.5, to 15 nm thick.

In another aspect, the portions (or portion for the chemical sensor) of the 2^{nd} SiO₂ layer under the corresponding plurality of sensor areas (or area for the chemical sensor) is absent and the thickness of the plurality of sensor areas (or area), as measured from the top of the corresponding dopant layers to the bottom of the corresponding silicon layers (or layer)(i.e., the thickness of the plurality of sensor membranes (or sensor membrane)), is from 50, 100, 150, 200, 250, 300, 350, 400, 450 to 500 μm. In another aspect, the thickness of the plurality of membranes (or membrane) is 200 μm. In another aspect, the thickness of the plurality of membranes (or membrane) is 100 μm. In another aspect, the thickness of the plurality of membranes (or membrane) is 50 μm.

A multilayer structure or sensing layer is a thin film is obtained by multiple consecutive depositions of a metal oxide and a dopant (e.g., SnO₂, then TiO₂, then SiO₂, then TiO₂, etc.).

In another aspect, the sensor is a multilayer chemical sensor, comprising:
(a) an oxidized silicon wafer, comprising: a silicon layer sandwiched between a top (1^{st}) silicon oxide (SiO₂) layer and a bottom (2^{nd}) SiO₂ layer, the top SiO₂ layer, comprising: a sensor area;
(b) a heating element in contact with the 1^{st} SiO₂ layer and located near at least one edge of the sensor area;
(c) a pair of electrical leads in contact with the 1^{st} SiO₂ layer and at least partly located on the sensor area;
(d) a sensing layer, comprising: alternating layers of metal oxide and dopant, wherein the sensing layer is located on the sensor area and the first metal oxide layer is in contact with at least a part of the pair of electrical leads and the 1^{st} SiO₂ layer.

In another aspect, the sensing layer, comprises: from 4, 5, 6, 7, 8, 9, 10, 11, 12, 13, 14, 15, 16, 17, 18, 19, to 20 layers (though typically there are an even number of layers with the dopant being the outermost layer). In another aspect, the sensing layer, comprises: 6 layers.

In another aspect, from 5-50% by volume of the sensing layer is the dopant. In another aspect, 5% by volume of the sensing layer is the dopant. In another aspect, 10% by volume of the sensing layer is the dopant. In another aspect, 15% by volume of the sensing layer is the dopant. In another aspect, 20% by volume of the sensing layer is the dopant.

### EXAMPLES

The following examples are meant to illustrate, not limit, the present invention.

### Example 1

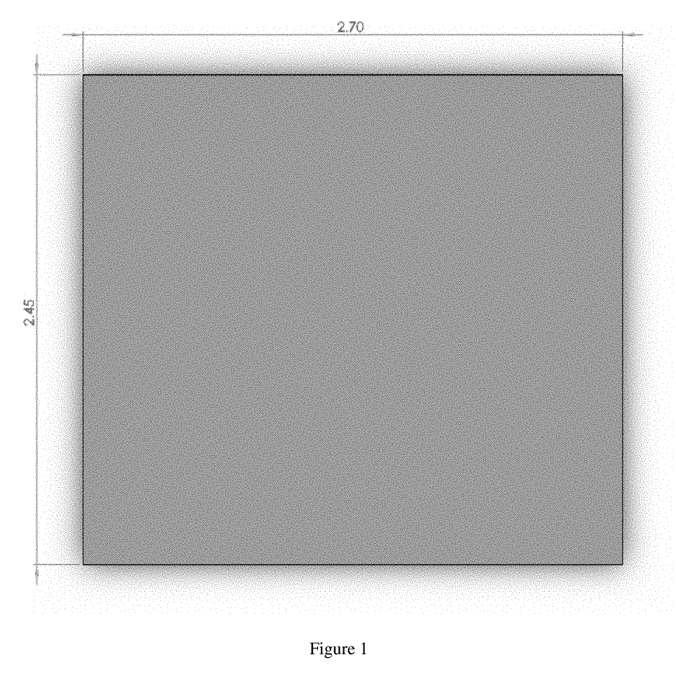

FIG. 1 shows the dimensions (mm) of a piece of flat glass. This is an example of a useful size of a piece of flat glass useful for one of Layers A-E.

### Example 2

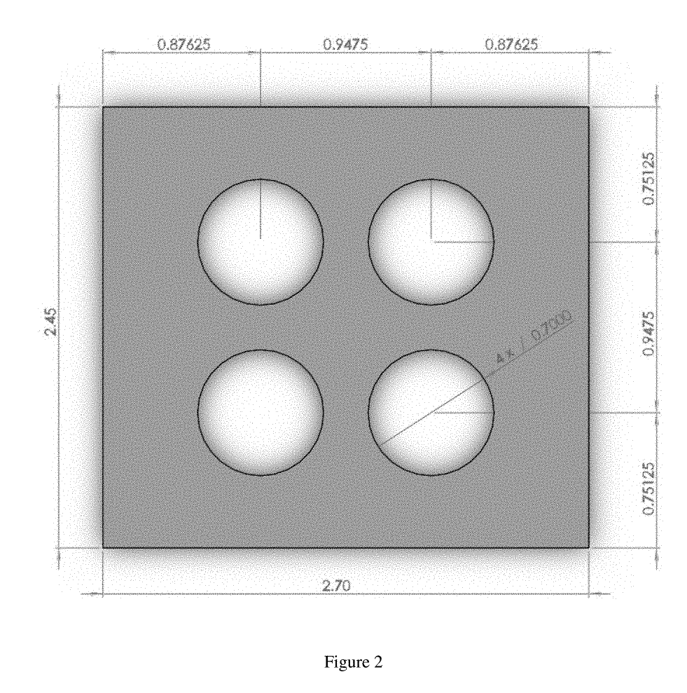

FIG. 2 shows the dimensions (mm) of a piece of flat glass with 4 circular cut outs (4 middle portions absent). This example could be used as any of Layers A-E.

### Example 3

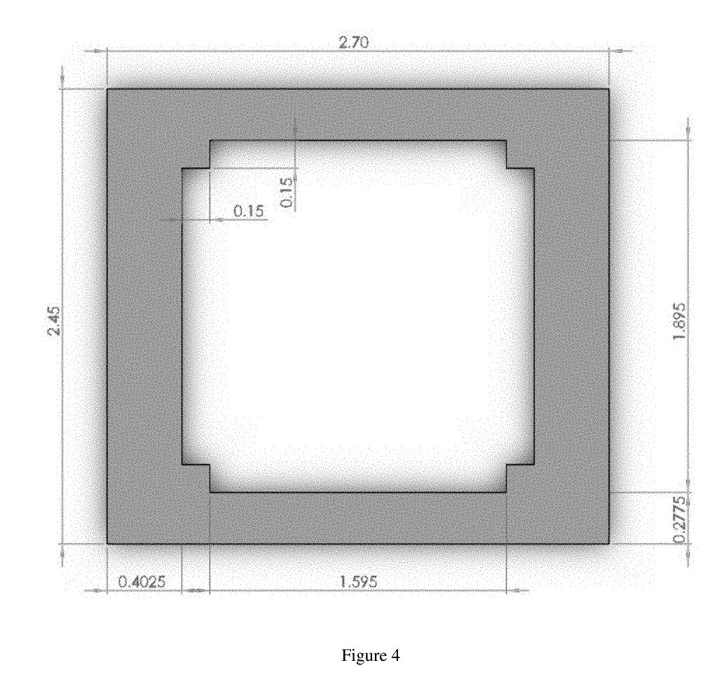

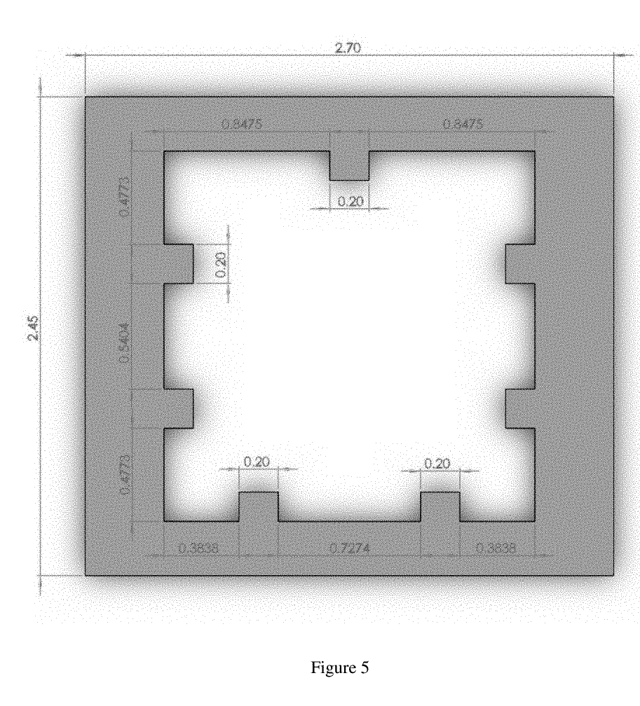

FIGS. 3-5 show pieces of flat glass with a cut out (1 middle portion absent). The protrusions or tabs (2 central tabs in FIG. 3, 4 corner tabs in FIG. 4, 7 central tabs in FIG. 5)) shown can be used to help house the sensory element if the example is used as Layer A. The protrusions or tabs can be used to overlap the sensory element if the example is used as Layer B and/or D.

### Example 4

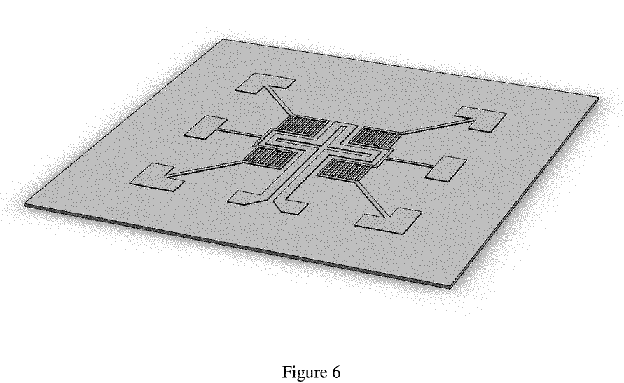

FIG. 6 shows a sensor glass layer wherein a sensory element is located on top of a piece of flat glass (Layer A). This example shows 4 sensor areas separated by a heating element (T-shape) and 6 electrodes extending away from the sensor areas. FIG. 7 shows the sensor glass layer of FIG. 6 wherein some the glass of Layer A near the edges of the sensory element has been removed (i.e., is partially absent).

### Example 5

FIG. 8 shows an expanded view of a glass-sensor structure having Layers A-E.

In this example, the sensory element is on top Layer A (the sensor glass layer of FIG. 7). Layer B (green layer), which is on top of Layer A, is missing a middle portion that is larger than the sensory element and therefore is not in contact with the sensory element. Layer C is missing a middle portion that partially overlaps the sensory element and the missing portion of Layer B, thereby creating an environmental connection with the sensory element. Layer D is missing a middle portion, which helps isolate the sensory element, both thermally and electrically. Layer E on the bottom is shown as a solid piece of flat glass.

FIG. 8A shows an expanded view of a glass-sensor structure like that described for FIG. 8, except that each of Layers A-E has holes of sufficient diameter to fit the electrical conductive pins shown extending through Layer E. The pins in FIG. 8A serve two purposes. First, the pins are useful as mechanical connectors that join Layers A-E. Second, the pins (specifically the portions extending below Layer E) are useful to facilitate the electrical connection of the sensor portion of the glass-sensor to external components (e.g., power source, detector, etc.).

FIG. 8B shows an expanded view of a glass-sensor structure like that described for FIG. 8, except that each of Layers A-E has holes of sufficient diameter to fit the pins shown projecting out of Layer E. The pins in FIG. 8B serve two purposes. First, the pins are useful as mechanical connectors that join Layers A-E. Second, the pins are useful to facilitate the electrical connection of the sensor portion of the glass-sensor to conductive pads. In FIG. 8B, Layer E shows conductive pads that are mounted on the top side of it. These pads are present to facilitate the electrical connection of the sensor portion of the glass-sensor to external components (e.g., power source, detector, etc.). The conductive pads are in electrical connection with the conductive pins. The conductive pins, as shown in FIG. 8B, pass through the conductive pads and into Layer E. The pin/pad connection is optionally facilitated, for example, by the presence of solder paste.

FIG. 9 is a collapsed view of the glass-sensory structure of FIG. 8.

FIG. 9A is a collapsed view of the glass-sensory structure of FIG. 8A.

FIG. 9B is a collapsed view of the glass-sensory structure of FIG. 8B.

### Example 6

FIG. 10 shows an expanded view of a glass-sensor structure having Layers C-A-E. In this example, the sensory element is on top Layer A (the sensor glass layer of FIG. 7). Layers B and D are absent. Layer C is missing a middle portion that partially overlaps the sensory element, thereby creating an environmental connection with the sensory element. Layer E on the bottom is shown as a solid piece of flat glass.

FIG. 11 is a collapsed view of the glass-sensor structure of FIG. 10.

### Example 7

FIG. 12 shows an expanded view of a glass-sensor structure having Layers A-E. In this example, the sensory element is in the plane of Layer A. Layer A shows contact on 2 full edges of the sensory element (the near and far sides of the sensory element) and also two smaller edge contact points (via protrusions or tabs). Layer B (green layer), which is on top of Layer A, is missing a middle portion and has 7 planar contact points that overlap with the top of the sensory element (protrusions or tabs extending over the sensory element). Layer C is missing a middle portion that partially overlaps the sensory element and the missing portion of Layer B, thereby creating an environmental connection with the sensory element. Layer D is missing a middle portion and has 4 planar contact points that overlap corners of the bottom of sensory element. Layer E on the bottom is shown as a solid piece of flat glass.

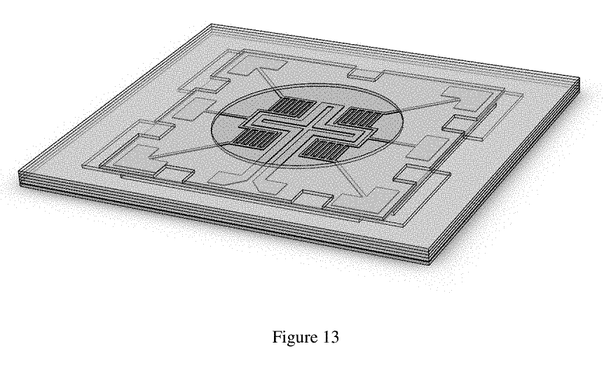

FIG. 13 shows a collapsed view of the glass-sensor structure of FIG. 12.

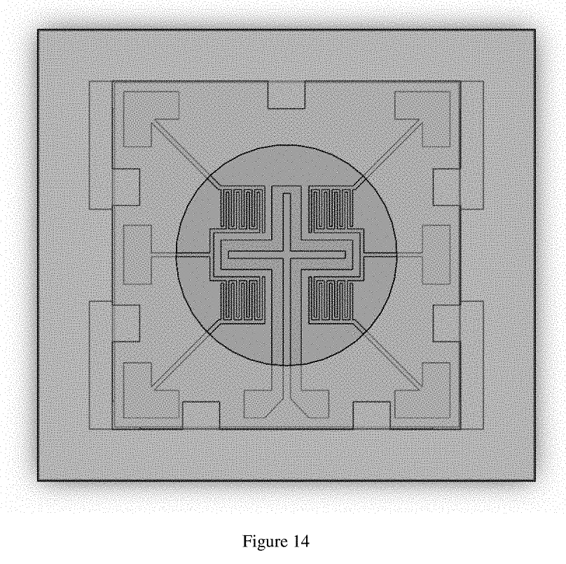

FIG. 14 shows a top view of the collapsed view of the glass-sensor structure of FIG. 12.

### Example 8

FIG. 15 shows an expanded view of a glass-sensor structure having Layers C-A-E. In this example, the sensory element is in the plane of Layer A. Layer A shows 4 edge contact points (protrusions or tabs extending out to the sensory element). Layers B and D are absent. Layers C and E are missing middle portions and each show 4 planar contact points that overlap the corners of the sensory element (top and bottom, respectively).

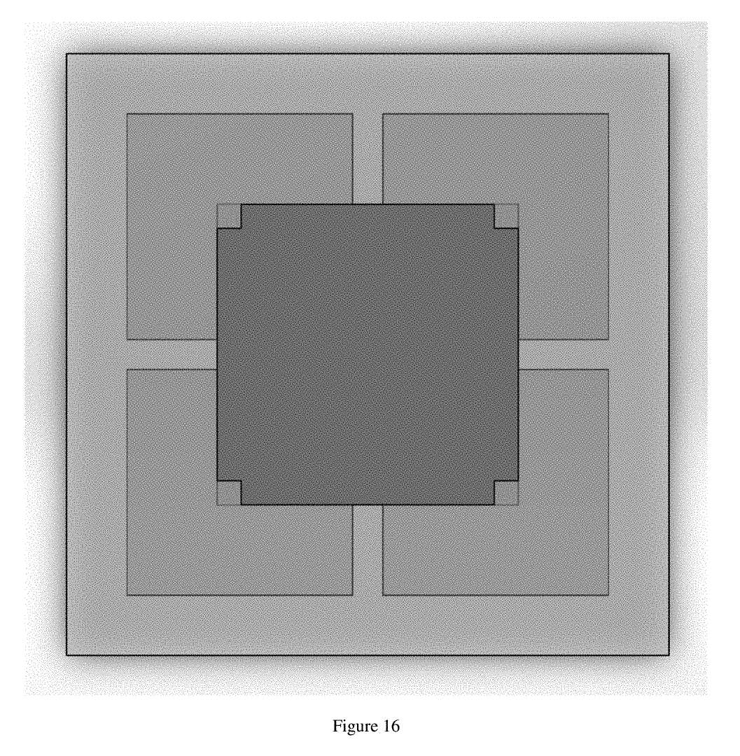

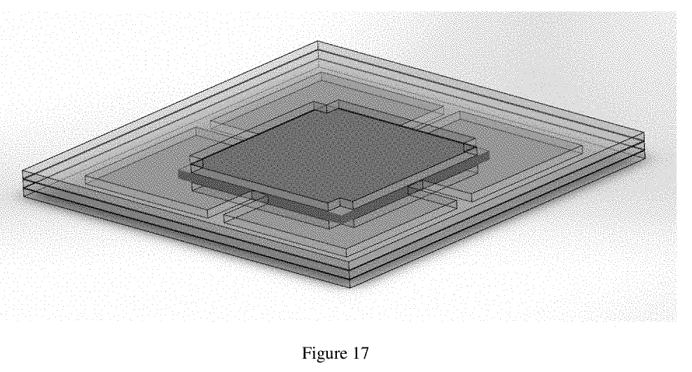

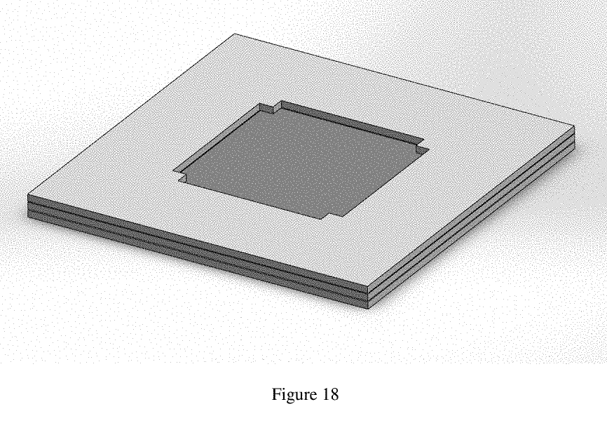

FIG. 16 shows the top view of the glass-sensor structure of FIG. 15. FIG. 17 shows a collapsed view of the glass-sensor structure of FIG. 15, with Layer C being shown as translucent. FIG. 18 is a collapsed view of the glass-sensor structure of FIG. 15.

### Example 9

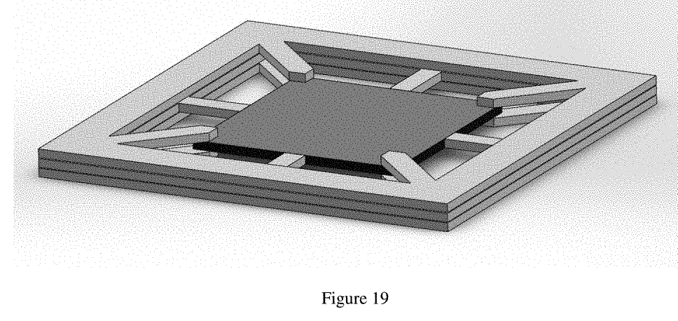

FIG. 19 shows another example of a glass-sensor structure similar to FIG. 15. In this figure, Layers C and E each have planar contact points that overlap the sensory element.

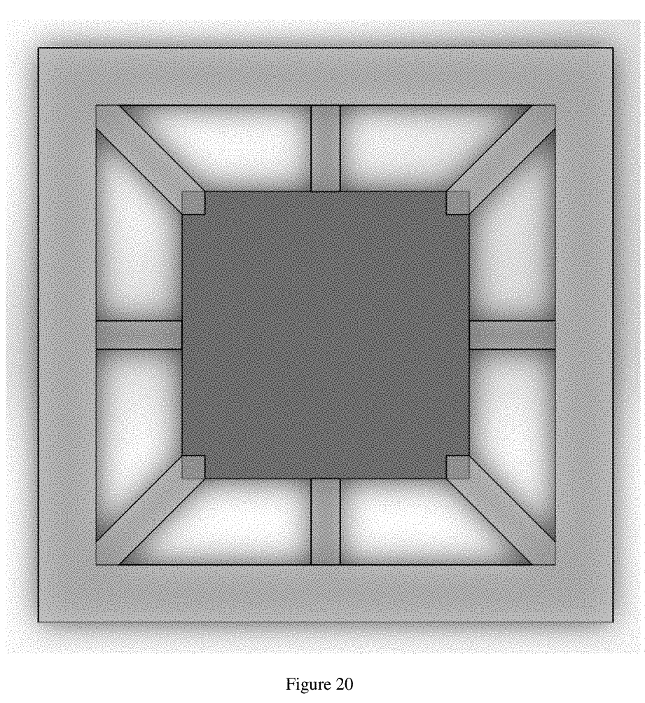

FIG. 20 shows the top view of the glass-sensor structure of FIG. 19.

### Example 10

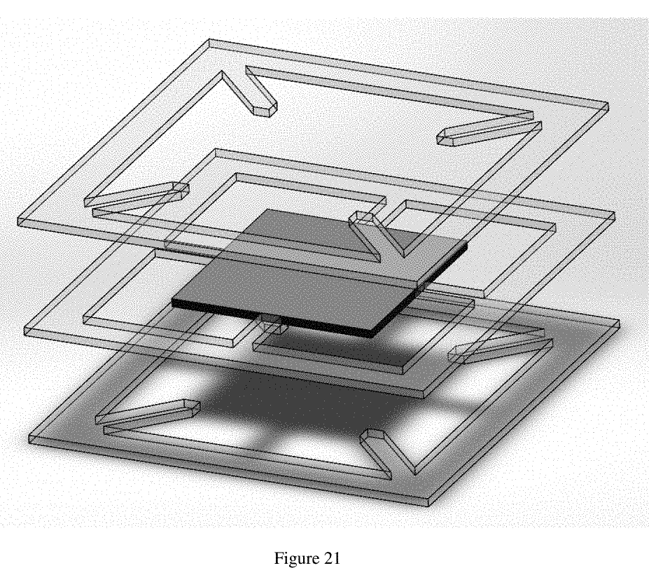

FIG. 21 shows an expanded view of a glass-sensor structure similar to that of FIG. 19, except that 4 middle portions of Layer A are missing.

### Example 11

FIG. 22 shows a collapsed view of a glass-sensor structure having Layers A-E. The sensory element in this example can be either on top of Layer A or in the plane of Layer A. In this example, Layer C is movable. The circumference of Layer C contains teeth, which allows for a gear (shown) to rotate Layer C either clockwise or counterclockwise. Movement of the gear can be powered by a device such as a stepper motor, which would allow for discreet movement of Layer C. As shown in FIG. 22, only one of the 4 openings in Layer B is exposed to the environment. By rotating Layer C each of the 4 openings in Layer B can be exposed to the environment, one at a time.

Numerous modifications and variations of the present invention are possible in light of the above teachings. It is therefore to be understood that within the scope of the appended claims, the invention may be practiced otherwise that as specifically described herein.

We claim:

1. A glass-sensor structure: comprising:
a sensor glass layer, comprising:
Layer A: a flat glass layer, optionally comprising: a reflective surface on its top or bottom; and,
a sensory element;
optionally, the glass-sensor structure, further comprises: from 1-4 layers selected from;
Layer B: a flat glass layer located on top of and at least partially in contact with Layer A, provided that if Layer B is present, Layer C is also present;
Layer C: a flat glass layer located on top of and at least partially in contact with Layer B, if present, or Layer A if Layer B is not present, and optionally comprising: a reflective surface on its top or bottom;
Layer D: a flat glass layer located on the bottom of and at least partially in contact with Layer A, provided that if Layer D is present, Layer E is also present; and
Layer E: a flat glass layer located on the bottom of and at least partially in contact with Layer D, if present, or Layer A if Layer D is not present, and optionally comprising: a reflective surface on its top or bottom.

2. The glass-sensor structure of claim 1, wherein:
the sensor glass layer, comprises: a plurality of sensory elements.

3. The glass-sensor structure of claim 1, wherein
the sensory element is in contact with at least a portion of the top of Layer A and has a smaller surface area than Layer A.

4. The glass-sensor structure of claim 3, wherein:
the glass of Layer A near the edges of the sensory element is partially absent.

5. The glass-sensor structure of claim 3, wherein:
the reflective surface is present on Layer A.

6. The glass-sensor structure of claim 5, wherein:
the reflective surface is on the bottom of Layer A.

7. The glass-sensor structure of claim 3, wherein:
Layers B and C are present.

8. The glass-sensor structure of claim 7, wherein:
a middle portion of Layer B is absent, such that an inner portion of Layer B is near the edges of the sensory element.

9. The glass-sensor structure of claim 8, wherein:
a middle portion of Layer C is absent.

10. The glass-sensor structure of claim 7, wherein:
the reflective surface is present on Layer C.

11. The glass-sensor structure of claim 10, wherein:
the reflective surface is on the top of Layer C.

12. The glass-sensor structure of claim 7, wherein:
Layers D and E are present.

13. The glass-sensor structure of claim 12, wherein:
the reflective surface is present on Layer E.

14. The glass-sensor structure of claim 15, wherein:
the reflective surface is on the bottom of Layer E.

15. The glass-sensor structure of claim 1, wherein
the sensory element is in the same plane as Layer A and is housed in an opening in the middle of Layer A that is at least the size of the sensory element.

16. The glass-sensor structure of claim 43, wherein:
Layers B, C, D, and E are present.

17. The glass-sensor structure of claim 1, further comprising: a plurality of mechanical pins.

18. The glass-sensor structure of claim 17, wherein the pins are electrically conductive and pass through and extend beyond the bottom of the structure.

19. The glass-sensor structure of claim 17, further comprising: a plurality of surface mount, electrically conductive pads present on the bottom layer of the structure.

20. The glass-sensor structure of claim 19, wherein the mechanical pins are electrically conductive and are in electrical connection with the pads.
